(19) United States
(12) Patent Application Publication
(10) Pub. No.: US 2025/0132235 A1
(43) Pub. Date: Apr. 24, 2025

(54) SEMICONDUCTOR DEVICE WITH SURROUNDING BUMP METALLIZATION AND METHOD THEREFOR

(71) Applicant: NXP USA, INC., AUSTIN, TX (US)

(72) Inventors: Kuan-Hsiang Mao, Kaohsiung (TW); Che Ming Fang, Kaohsiung city (TW); Wen Yuan Chuang, Kaohsiung (TW); Wen Hung Huang, Kaosiung (TW)

(21) Appl. No.: 18/489,173

(22) Filed: Oct. 18, 2023

(51) Int. Cl. H01L 23/498; H01L 23/00

(52) U.S. Cl. CPC H01L 23/49816; H01L 23/49822; H01L 23/49838; H01L 24/08; H01L 2224/08245; H01L 2924/182

(57) ABSTRACT

A method of manufacturing a semiconductor device is provided. The method includes forming a first non-conductive layer over a top side a semiconductor die and patterning the first non-conductive layer to form an opening exposing a top surface of a bond of the semiconductor die. A metal trace of a redistribution layer is formed over a portion of the first non-conductive layer and exposed top surface of the bond pad. A surrounding bump metallization (SBM) structure is formed on a portion of the metal trace. The SBM structure includes a plurality of vertical metal wall segments surrounding a central opening.

### BACKGROUND

### Field

This disclosure relates generally to semiconductor device packaging, and more specifically, to a semiconductor device with a surrounding bump metallization and method of forming the same.

### Related Art

Today, there is an increasing trend to include sophisticated semiconductor devices in products and systems that are used every day. These sophisticated semiconductor devices may include features for specific applications which may impact the configuration of the semiconductor device packages, for example. For some features and applications, the configuration of the semiconductor device packages may be susceptible to lower reliability, lower performance, and higher product or system costs. Accordingly, significant challenges exist in accommodating these features and applications while minimizing the impact on semiconductor devices' reliability, performance, and costs.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 illustrates, in a simplified plan view, an example semiconductor device having a surrounding bump metallization structure in accordance with an embodiment.

FIG. 2 through FIG. 8 illustrate, in simplified cross-sectional views, the example semiconductor device taken along line A-A of FIG. 1 at various stages of manufacture in accordance with an embodiment.

FIG. 9A through FIG. 9C illustrate, in simplified plan views, example surrounding bump metallization structures of the semiconductor device in accordance with an embodiment.

### DETAILED DESCRIPTION

Generally, there is provided, a semiconductor device with a surrounding bump metallization. The semiconductor device includes a patterned redistribution layer. A plurality of interconnections traces are formed from the patterned redistribution layer. Each interconnection trace includes a first portion connected to a top surface of a respective bond pad and a second portion configured as a base for formation of a surrounding bump metallization structure. A plurality of surrounding bump metallization structures are formed on respective interconnection traces. Each of surrounding bump metallization structure includes a plurality of vertical metal wall segments formed around an outer perimeter region of the second portion of the interconnection trace. A central opening or cavity is formed by the surrounding plurality of the vertical metal wall segments. Each of the vertical metal wall segments is separated from a neighboring vertical metal wall segment by a vertical gap. Each of the surrounding bump metallization structures is configured to serve as a socket for receiving a ball connector. The vertical gap allows air to vent as the ball connector material is melted. The width of the gap is chosen such that it is large enough for air to escape and small enough to keep the melted ball connector material from oozing out of the socket. By forming the surrounding bump metallization structures in this manner, the ball connections with semiconductor device are more robust and provide superior reliability along with tighter ball pitch control.

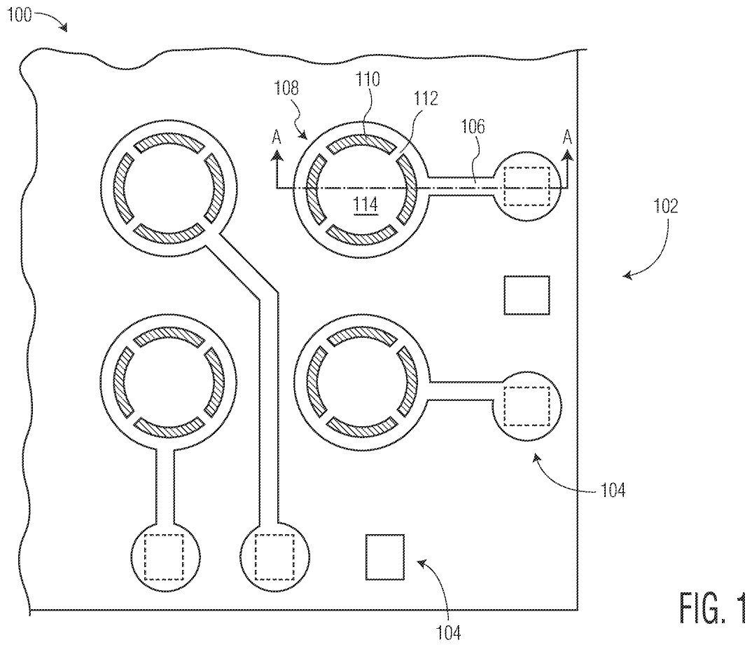

FIG. 1 illustrates, in a simplified plan view, a portion of an example semiconductor device 100 having a surrounding bump metallization (SBM) structure in accordance with an embodiment. The device 100 includes a semiconductor die 102, bond pads 104 formed at the top side of the semiconductor die, conductive (e.g., metal) interconnections traces 106 of a patterned redistribution layer (RDL) formed over the semiconductor die 102, and a plurality of SBM structures 108 formed on respective traces 106. The term “conductive,” as used herein, generally refers to electrical conductivity unless otherwise described. In this embodiment, each of the interconnections traces 106 includes a first portion directly connected to a top surface of a respective bond pad 104 and a second portion configured as a base for formation of a SBM structure 108.

In this embodiment, the SBM structure includes a plurality of vertical metal wall segments 110 formed around an outer perimeter region of the second portion of the trace 106. The vertical metal wall segments 110 are arranged to substantially surround a central opening or cavity 114. Each of the vertical metal wall segments 110 is separated from a neighboring vertical metal wall segment by a respective vertical gap 112. The arrangement of the vertical metal wall segments 110 surrounding the central opening 114 may be characterized as a socket structure configured to receive a ball connector (e.g., solder ball) at a subsequent stage of manufacture, for example. The vertical gap 112 is therefore configured to have a predetermined width such that the gap width is large enough to vent air/gas when the ball connector is reflowed yet small enough to prevent reflowed material from extending significantly beyond an outer perimeter formed by the plurality of vertical metal wall segments 110.

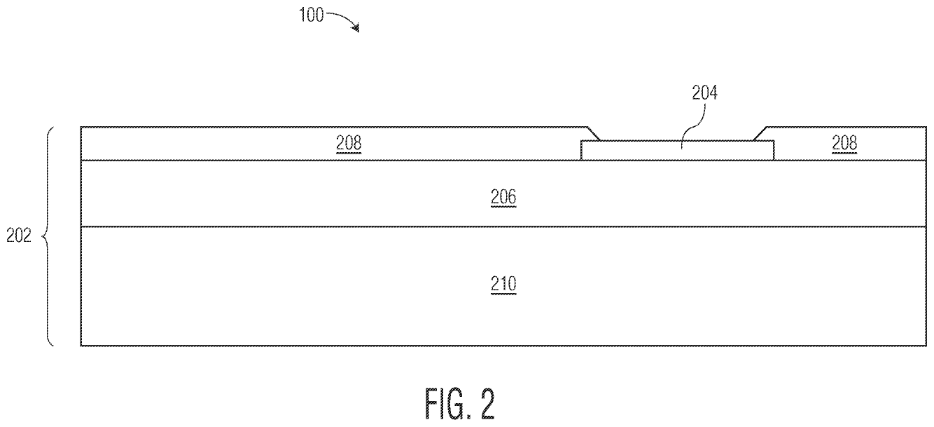

The number, shape, and arrangement of the vertical metal wall segments 110 and RDL interconnection traces 106 are chosen for illustration purposes. Some features of the semiconductor device 100 such as intermediate layers disposed between the semiconductor die 102 and the RDL are not shown for illustration purposes. Even though the embodiment of FIG. 1 is depicted in a “fan-in” configuration, embodiments in other configurations (e.g., “fan-out”) are anticipated by this disclosure. Cross-sectional views of the example semiconductor device 100 taken along line A-A of FIG. 1 at stages of manufacture are depicted in FIG. 2 through FIG. 8.

FIG. 2 illustrates, in a simplified cross-sectional view, the example semiconductor device 100 at a stage of manufacture in accordance with an embodiment. At this stage of manufacture, the semiconductor device 100 includes a semiconductor die 202. In this embodiment, the semiconductor die 202 includes a substrate region (e.g., bulk) 210, an active region (e.g., circuitry, interconnect) 206 formed at an active side of the semiconductor die, a bond pad 204 conductively connected to the circuitry and/or interconnect of the active region, and a final passivation layer 208 formed over the active side of the semiconductor die. In some embodiments, the semiconductor die 202 may be provided in a wafer form or portion of a wafer. In some embodiments (e.g., wafer-level chip-scale packaging), the semiconductor device 100 may be include an encapsulant (e.g., epoxy molding compound) formed over the backside of the semiconductor die 202. The semiconductor die 202 may include any number of conductive interconnect layers and passivation layers. For illustration purposes, the bond pad 204 at a top surface and the overlying final passivation layer 208 are depicted. In this embodiment, the semiconductor die 202 depicted in FIG. 2 corresponds to the semiconductor die 102 of FIG. 1.

The semiconductor die 202 is configured and arranged in an active side up orientation. The bond pad 204 at the active side is configured for connection to printed circuit board (PCB) by way of a redistribution layer, SBM structure, and conductive connectors formed at subsequent stages, for example. The semiconductor die 202 may be formed from any suitable semiconductor material, such as silicon, germanium, gallium arsenide, gallium nitride, silicon nitride, silicon carbide, and the like. The semiconductor die 202 may further include any digital circuits, analog circuits, RF circuits, power circuits, memory, processor, MEMS, sensors, the like, and combinations thereof.

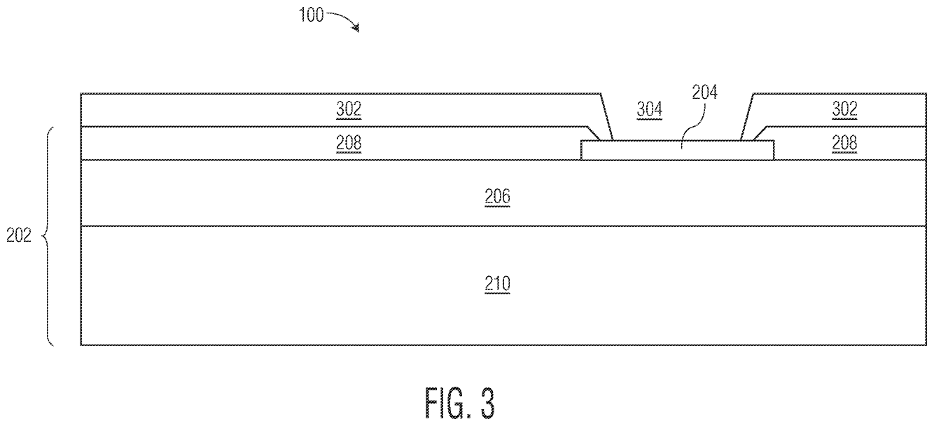

FIG. 3 illustrates, in a simplified cross-sectional view, the example semiconductor device 100 at a subsequent stage of manufacture in accordance with an embodiment. At this stage of manufacture, the semiconductor device 100 includes a first non-conductive (e.g., dielectric) layer 302 formed over the semiconductor die 202. The non-conductive layer 302 is deposited or otherwise applied on the top surface of the semiconductor die 202. The non-conductive layer 302 may be formed from suitable non-conducting polymer materials such as polyimide, PBO, and the like, for example. In this embodiment, the non-conductive layer 302 is patterned to form an opening 304. The opening 304 is located directly over the bond pad 204 such that a substantial portion of the top surface of the bond pad 204 is exposed (e.g., not covered with the non-conductive layer 302).

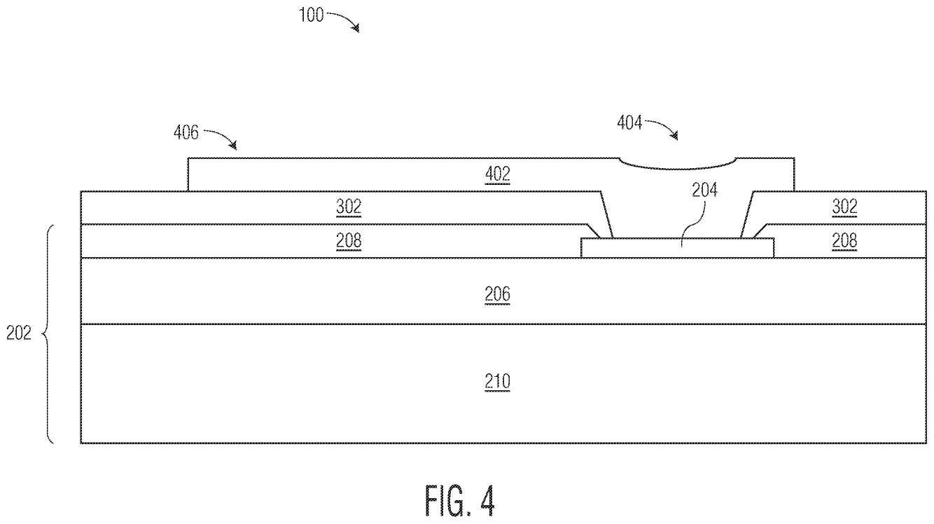

FIG. 4 illustrates, in a simplified cross-sectional view, the example semiconductor device 100 at a subsequent stage of manufacture in accordance with an embodiment. At this stage of manufacture, the semiconductor device 100 includes a metal RDL formed over the non-conductive layer 302 and exposed portion of the bond pad 204. The RDL may be formed by way of sputtering or electroplating a metal material (e.g., copper), for example. In this embodiment, the RDL is patterned to form a plurality of RDL interconnection traces such as the interconnection trace 402 depicted in FIG. 4. The interconnection trace 402 may correspond to the interconnection trace 106 depicted in FIG. 1, for example. In this embodiment, interconnection trace 402 includes a first portion 404 directly connected to the top surface of the bond pad 204 and a second portion 406 configured as a base for formation of an SBM structure at a subsequent stage of manufacture. The interconnection trace 402 is configured to interconnect the bond pad 204 with the SBM structure formed at a subsequent stage, for example.

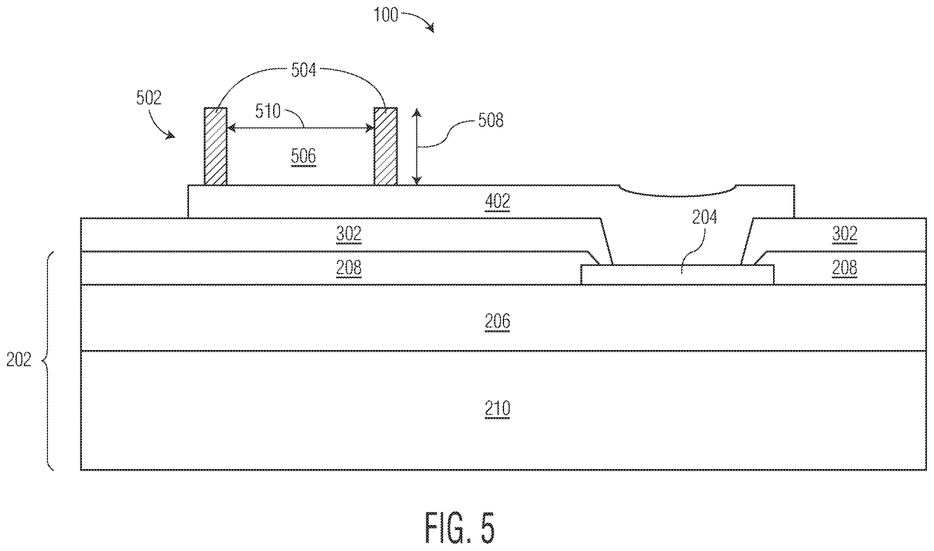

FIG. 5 illustrates, in a simplified cross-sectional view, the example semiconductor device 100 at a subsequent stage of manufacture in accordance with an embodiment. At this stage of manufacture, the semiconductor device 100 includes a metal (e.g., copper) SBM structure 502 formed on the exposed portion of the interconnection trace 402. In this embodiment, the SBM structure includes a plurality of vertical metal wall segments 504 arranged to substantially surround a central opening or cavity 506. Each of the vertical metal wall segments 504 is separated from a neighboring vertical metal wall segment by a respective vertical gap (not shown). The arrangement of the vertical metal wall segments 504 surrounding the central opening 506 may serve as a socket structure for placement of a ball connector (e.g., solder ball) at a subsequent stage of manufacture, for example. In this embodiment, the vertical metal wall segments 504 of the SBM structure 502 maybe formed by way of a plating process. For example, a seed layer (not shown) may be formed and patterned on an exposed portion of the interconnection trace 402 (e.g., second portion 406 of FIG. 4). The plurality of vertical metal wall segments 504 of the SBM structure are formed as electroplated copper pillars by utilizing the patterned seed layer, for example. In this embodiment, the vertical metal wall segments 504 are formed having a substantially uniform height dimension 508 and a (shortest) horizontal width or diameter dimension 510 across the central opening 506. In this embodiment, it is desirable for the height dimension 508 to be approximately in a range of 40-60% of the horizontal width or diameter dimension 510.

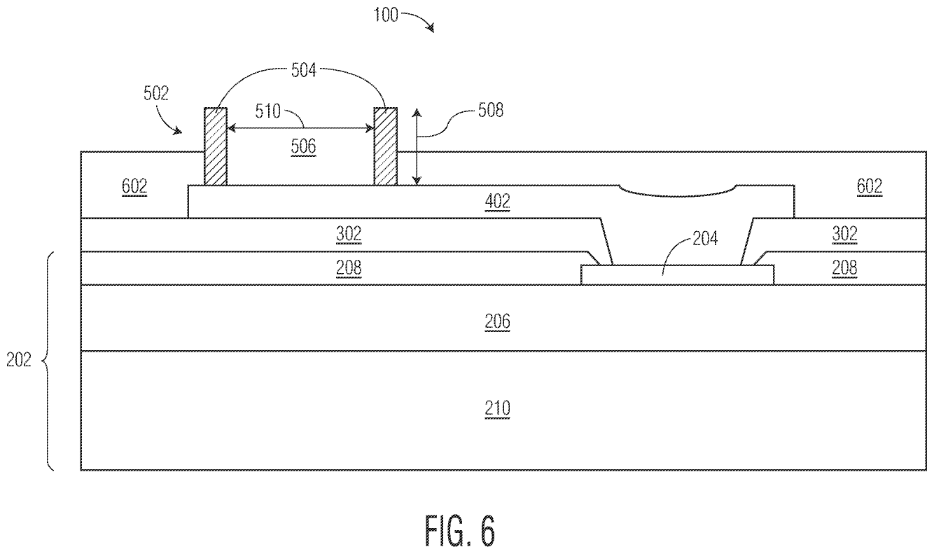

FIG. 6 illustrates, in a simplified cross-sectional view, the example semiconductor device 100 at a subsequent stage of manufacture in accordance with an embodiment. At this stage of manufacture, the semiconductor device 100 includes a second non-conductive (e.g., dielectric) layer 602 formed over the first non-conductive layer 302 and the exposed portions of the interconnection trace 402. The non-conductive layer 602 is deposited or otherwise applied on the top surface of the semiconductor die 202. The non-conductive layer 602 is patterned to form an opening through the non-conductive layer 602 such that the central opening 506 is void of the non-conductive layer 602. The patterned opening through the non-conductive layer 602 is located directly over the SBM structure 502 such that the portion of the interconnection trace 402 at the bottom of the central opening 506 remains exposed. In this embodiment, a portion of the non-conductive layer 602 surrounds an outer perimeter of the SBM structure 502.

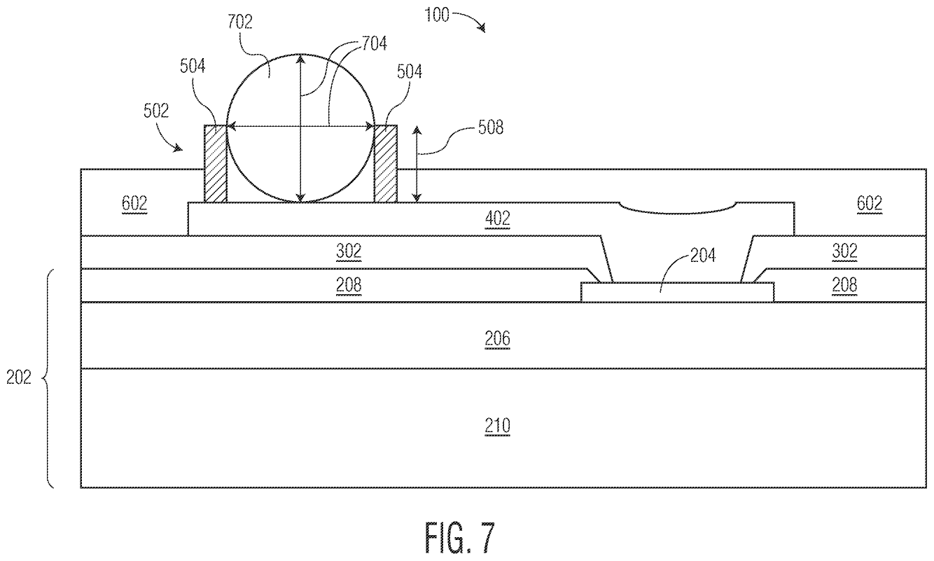

FIG. 7 illustrates, in a simplified cross-sectional view, the example semiconductor device 100 at a subsequent stage of manufacture in accordance with an embodiment. At this stage of manufacture, the semiconductor device 100 includes a ball connector 702 placed into the central opening of the SBM structure 502. When placed into the SBM structure, the plurality of vertical metal wall segments 504 substantially surrounds the ball connector 702. In this embodiment, the ball connector 702 may be characterized as a solder ball being formed from a solder or solder alloy material. In some embodiments, the ball connector 702 may be formed as a solder coated sphere having a solid metal core (e.g., copper, copper alloy). In this embodiment, the ball connector 702 is a substantially round sphere having a maximum diameter dimension 704. In this embodiment, it is desirable for the height dimension 508 of the vertical metal wall segments 504 to be approximately in a range of 40-60% of the maximum diameter dimension 704 the ball connector 702. By keeping the vertical metal wall segments height dimension 508 roughly half of the ball connector diameter dimension 704, an ample dome of ball connector material will remain above the top of the vertical metal wall segments 504 after reflowing at a subsequent stage.

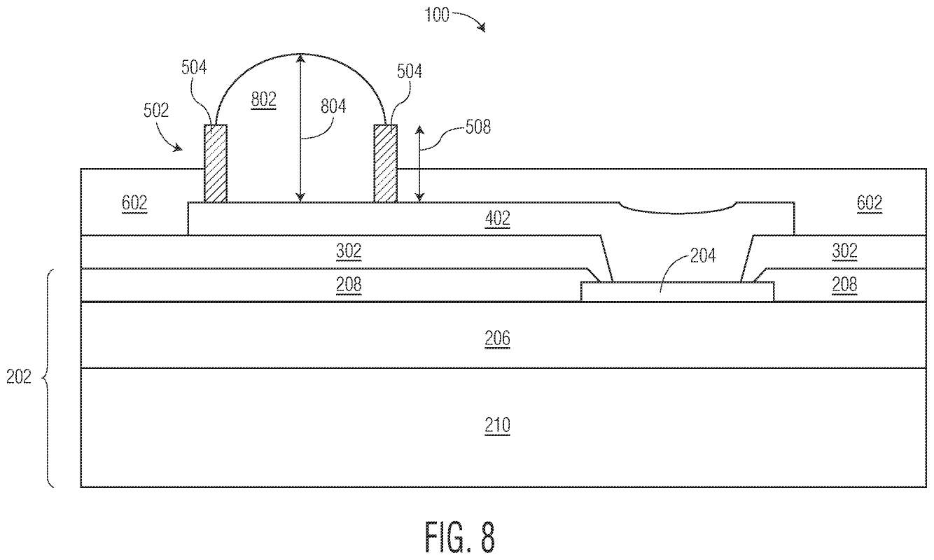

FIG. 8 illustrates, in a simplified cross-sectional view, the example semiconductor device 100 at a subsequent stage of manufacture in accordance with an embodiment. At this stage of manufacture, the semiconductor device 100 includes a reflowed ball connector 802 (e.g., reflowed solder ball) wetted to the SBM structure 502 and underlying portion of the interconnection trace 402. In this embodiment, the semiconductor device is subjected to a reflow thermal cycle such that the ball connector 702 depicted in FIG. 7 is reflowed to form the reflowed ball connector 802 depicted in FIG. 8. During the reflow thermal cycle, the ball connector material melts and wets to the inner sidewall surfaces of the SBM structure while venting any potentially trapped air or gases through the vertical gaps located between the vertical metal wall segments 504. In this embodiment, the ball connector material melts and is wetted to the inner sidewalls of the plurality of vertical metal wall segments 504 and the portion of the trace 402 surrounded by the plurality of vertical metal wall segments 504 exposed at the bottom of the SBM structure 502. By reflowing the ball connector 802 in this manner, a robust and reliable joint and connection with the SBM structure 502 is formed without voids.

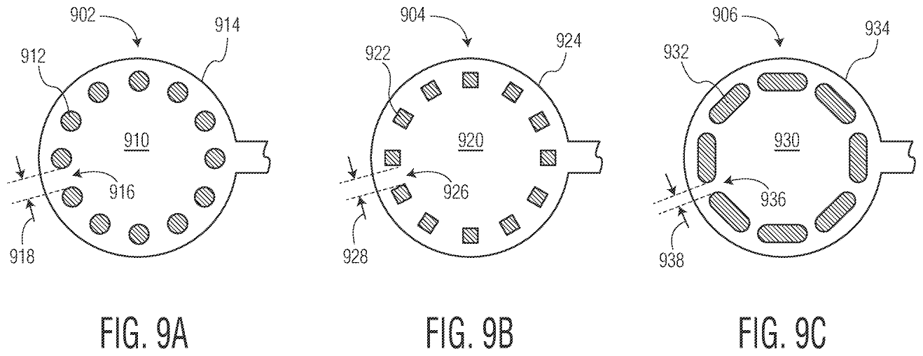

FIG. 9A through FIG. 9C illustrate, in simplified plan views, example SBM structures of the semiconductor device 100 at a stage of manufacture in accordance with an embodiment. Each of the plan views depicted in FIG. 9A through FIG. 9C include a focused portion of the semiconductor device 100 showing example alternative SBM structures for the SBM structure 108 and consistent with the stage of manufacture depicted in FIG. 1.

FIG. 9A illustrates, in a simplified plan view, the focused portion of the example semiconductor device 100 with an example SBM structure 902 in accordance with an embodiment. In this embodiment, the SBM structure 902 includes a plurality of vertical metal wall segments 912 substantially surrounding a central opening 910. In this embodiment, each of the vertical metal wall segments 912 is formed as a substantially round vertical wall segment. The plurality of vertical metal wall segments 912 of the SBM structure 902 may be formed as electroplated copper pillars, for example. The plurality of vertical metal wall segments 912 are arranged in a series around an outer perimeter base portion of the interconnection trace 914. Each of the vertical metal wall segments 912 is separated from a neighboring vertical metal wall segment by a vertical gap 916. In this embodiment, the vertical gap is formed having a predetermined lateral width dimension 918 in a range with a minimum value of approximately 10 microns and maximum value chosen such that reflowed ball connector material does not significantly flow past an outer perimeter of the SBM structure 902.

FIG. 9B illustrates, in a simplified plan view, the focused portion of the example semiconductor device 100 with an example SBM structure 904 in accordance with an embodiment. In this embodiment, the SBM structure 904 includes a plurality of vertical metal wall segments 922 substantially surrounding a central opening 920. In this embodiment, each of the vertical metal wall segments 922 is formed as a substantially square or rectilinear vertical wall segment. The plurality of vertical metal wall segments 922 of the SBM structure 904 may be formed as electroplated copper pillars, for example. The plurality of vertical metal wall segments 922 are arranged in a series around an outer perimeter base portion of the interconnection trace 924. Each of the vertical metal wall segments 922 is separated from a neighboring vertical metal wall segment by a vertical gap 926. In this embodiment, the vertical gap is formed having a predetermined lateral width dimension 928 in a range with a minimum value of approximately 10 microns and maximum value chosen such that reflowed ball connector material does not significantly flow past an outer perimeter of the SBM structure 904.

FIG. 9C illustrates, in a simplified plan view, the focused portion of the example semiconductor device 100 with an example SBM structure 906 in accordance with an embodiment. In this embodiment, the SBM structure 906 includes a plurality of vertical metal wall segments 932 substantially surrounding a central opening 930. In this embodiment, each of the vertical metal wall segments 932 is formed as a substantially oval vertical wall segment. The plurality of vertical metal wall segments 932 of the SBM structure 906 may be formed as electroplated copper pillars, for example. The plurality of vertical metal wall segments 932 are arranged in a series around an outer perimeter base portion of the interconnection trace 934. Each of the vertical metal wall segments 932 is separated from a neighboring vertical metal wall segment by a vertical gap 936. In this embodiment, the vertical gap is formed having a predetermined lateral width dimension 938 in a range with a minimum value of approximately 10 microns and maximum value chosen such that reflowed ball connector material does not significantly flow past an outer perimeter of the SBM structure 906.

Generally, there is provided, a method including forming a first non-conductive layer over a top side a semiconductor die; patterning the first non-conductive layer to form an opening exposing a top surface of a bond pad of the semiconductor die; forming a metal trace of a redistribution layer (RDL) over a portion of the first non-conductive layer and exposed top surface of the bond pad; and forming a surrounding bump metallization (SBM) structure on a portion of the metal trace, the SBM structure including a plurality of vertical metal wall segments surrounding a central opening. The method may further include placing a ball connector into the central opening of the SBM structure such that the plurality of vertical metal wall segments substantially surround the ball connector. A height dimension of the plurality of vertical metal wall segments may be approximately in a range of 40% to 60% of the largest diameter of the ball connector. The method may further include reflowing the ball connector such that conductive material of the ball connector wets to the entire inner sidewalls of the plurality of vertical metal wall segments of the SBM. The each of the vertical metal wall segments of plurality of vertical metal wall segments may be separated from a neighboring vertical metal wall segment by a respective gap, the gap having a predetermined lateral dimension. The predetermined lateral dimension of the gap may be substantially 10 microns or greater. The gap may extend vertically from the portion of the metal trace to a top of the plurality of vertical metal wall segments. The forming the SBM structure may include forming the plurality of vertical metal wall segments as electroplated copper pillars. The method may further include forming a second non-conductive layer over the first non-conductive layer and exposed portions of the metal trace; and patterning the second non-conductive layer such that a top surface of the metal trace is exposed in the central opening of the SBM structure.

In another embodiment, there is provided, a semiconductor device including a first non-conductive layer over a top side a semiconductor die, an opening in the first non-conductive layer exposes a top surface of a bond pad of the semiconductor die; a metal trace of a redistribution layer formed over a portion of the first non-conductive layer and exposed top surface of the bond pad; and a surrounding bump metallization (SBM) structure formed on a portion of the metal trace, the SBM structure including a plurality of vertical metal wall segments surrounding a central opening. The plurality of vertical metal wall segments of the SBM structure may be formed as electroplated copper pillars. A height dimension of the plurality of vertical metal wall segments may be substantially in a range of 40% to 60% of a horizontal width or diameter of the central opening. The semiconductor device may further include a reflowed ball connector surrounded by the plurality of vertical metal wall segments such that conductive material of the ball connector may be wetted to the inner sidewalls of the plurality of vertical metal wall segments and to the portion of the metal trace. A height dimension of the plurality of vertical metal wall segments may be at least 50% of a maximum height dimension of the reflowed ball connector. Each vertical metal wall segment of the plurality of vertical metal wall segments may be separated from a neighboring vertical wall segment by way of a gap, the gap having a predetermined lateral dimension.

In yet another embodiment, there is provided, a method including forming a first non-conductive layer over a top side a semiconductor die; patterning the first non-conductive layer to form an opening exposing a top surface of a bond pad of the semiconductor die; forming a metal trace of a redistribution layer (RDL) over a portion of the first non-conductive layer and exposed top surface of the bond pad; forming a surrounding bump metallization (SBM) structure on a portion of the metal trace, the SBM structure including a plurality of vertical metal wall segments surrounding a central opening, each vertical metal wall segment separated from a neighboring vertical wall segment by way of a vertical gap; forming a second non-conductive layer over the first non-conductive layer and exposed portions of the metal trace; and patterning the second non-conductive layer such that a top surface of the metal trace is exposed in the central opening of the SBM structure. The method may further include placing a ball connector into the central opening of the SBM structure such that the plurality of vertical metal wall segments substantially surround the ball connector. The method may further include reflowing the ball connector such that conductive material of the ball connector wets to the entire inner sidewalls of the plurality of vertical metal wall segments of the SBM structure and to the portion of the metal trace. The vertical gap may be formed having a predetermined lateral dimension, the predetermined lateral dimension substantially 10 microns or greater. The plurality of vertical metal wall segments of the SBM structure may be formed as electroplated copper pillars.

By now, it should be appreciated that there has been provided a semiconductor device with a surrounding bump metallization. The semiconductor device includes a patterned redistribution layer. A plurality of interconnections traces are formed from the patterned redistribution layer. Each interconnection trace includes a first portion connected to a top surface of a respective bond pad and a second portion configured as a base for formation of a surrounding bump metallization structure. A plurality of surrounding bump metallization structures are formed on respective interconnection traces. Each of surrounding bump metallization structure includes a plurality of vertical metal wall segments formed around an outer perimeter region of the second portion of the interconnection trace. A central opening or cavity is formed by the surrounding plurality of the vertical metal wall segments. Each of the vertical metal wall segments is separated from a neighboring vertical metal wall segment by a vertical gap. Each of the surrounding bump metallization structures is configured to serve as a socket for receiving a ball connector. The vertical gap allows air to vent as the ball connector material is melted. The width of the gap is chosen such that it is large enough for air to escape and small enough to keep the melted ball connector material from oozing out of the socket. By forming the surrounding bump metallization structures in this manner, the ball connections with semiconductor device are more robust and provide superior reliability along with tighter ball pitch control.

The terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed is:

1. A method comprising:
forming a first non-conductive layer over a top side a semiconductor die;
patterning the first non-conductive layer to form an opening exposing a top surface of a bond pad of the semiconductor die;
forming a metal trace of a redistribution layer (RDL) over a portion of the first non-conductive layer and exposed top surface of the bond pad; and
forming a surrounding bump metallization (SBM) structure on a portion of the metal trace, the SBM structure including a plurality of vertical metal wall segments surrounding a central opening.

2. The method of claim 1, further comprising placing a ball connector into the central opening of the SBM structure such that the plurality of vertical metal wall segments substantially surround the ball connector.

3. The method of claim 2, wherein a height dimension of the plurality of vertical metal wall segments is approximately in a range of 40% to 60% of a largest diameter of the ball connector.

4. The method of claim 2, further comprising reflowing the ball connector such that conductive material of the ball connector wets to the entire inner sidewalls of the plurality of vertical metal wall segments of the SBM.

5. The method of claim 1, wherein the each of the vertical metal wall segments of plurality of vertical metal wall segments is separated from a neighboring vertical metal wall segment by a respective gap, the gap having a predetermined lateral dimension.

6. The method of claim 5, wherein the predetermined lateral dimension of the gap is substantially 10 microns or greater.

7. The method of claim 5, wherein the gap extends vertically from the portion of the metal trace to a top of the plurality of vertical metal wall segments.

8. The method of claim 1, wherein forming the SBM structure includes forming the plurality of vertical metal wall segments as electroplated copper pillars.

9. The method of claim 1, further comprising:
forming a second non-conductive layer over the first non-conductive layer and exposed portions of the metal trace; and
patterning the second non-conductive layer such that a top surface of the metal trace is exposed in the central opening of the SBM structure.

10. A semiconductor device comprising:
a first non-conductive layer over a top side a semiconductor die, an opening in the first non-conductive layer exposes a top surface of a bond pad of the semiconductor die;
a metal trace of a redistribution layer formed over a portion of the first non-conductive layer and exposed top surface of the bond pad; and
a surrounding bump metallization (SBM) structure formed on a portion of the metal trace, the SBM structure including a plurality of vertical metal wall segments surrounding a central opening.

11. The semiconductor device of claim 10, wherein the plurality of vertical metal wall segments of the SBM structure are formed as electroplated copper pillars.

12. The semiconductor device of claim 10, wherein a height dimension of the plurality of vertical metal wall segments is substantially in a range of 40% to 60% of a horizontal width or diameter of the central opening.

13. The semiconductor device of claim 10, further comprising a reflowed ball connector surrounded by the plurality of vertical metal wall segments such that conductive material of the ball connector is wetted to the inner sidewalls of the plurality of vertical metal wall segments and to the portion of the metal trace.

14. The semiconductor device of claim 13, wherein a height dimension of the plurality of vertical metal wall segments is at least 50% of a maximum height dimension of the reflowed ball connector.

15. The semiconductor device of claim 10, wherein each vertical metal wall segment of the plurality of vertical metal wall segments is separated from a neighboring vertical wall segment by way of a gap, the gap having a predetermined lateral dimension.

16. A method comprising:
forming a first non-conductive layer over a top side a semiconductor die;
patterning the first non-conductive layer to form an opening exposing a top surface of a bond pad of the semiconductor die;
forming a metal trace of a redistribution layer (RDL) over a portion of the first non-conductive layer and exposed top surface of the bond pad;
forming a surrounding bump metallization (SBM) structure on a portion of the metal trace, the SBM structure including a plurality of vertical metal wall segments surrounding a central opening, each vertical metal wall segment separated from a neighboring vertical wall segment by way of a vertical gap;
forming a second non-conductive layer over the first non-conductive layer and exposed portions of the metal trace; and
patterning the second non-conductive layer such that a top surface of the metal trace is exposed in the central opening of the SBM structure.

17. The method of claim 16, further comprising placing a ball connector into the central opening of the SBM structure such that the plurality of vertical metal wall segments substantially surround the ball connector.

18. The method of claim 17, further comprising reflowing the ball connector such that conductive material of the ball connector wets to the entire inner sidewalls of the plurality of vertical metal wall segments of the SBM structure and to the portion of the metal trace.

19. The method of claim 16, wherein the vertical gap is formed having a predetermined lateral dimension, the predetermined lateral dimension substantially 10 microns or greater.

20. The method of claim 16, wherein the plurality of vertical metal wall segments of the SBM structure are formed as electroplated copper pillars.
